(19) United States
(12) Patent Application Publication
(10) Pub. No.: US 2004/0106231 A1
(43) Pub. Date: Jun. 3, 2004

(54) Compact electronic device and process of manufacturing the same

(76) Inventor: Rong-Huei Wang, Hsinchu (TW)

Correspondence Address: Mr. Joseph A. Sawyer, Jr., SAWYER LAW GROUP LLP, Embarcadero Corporate Center, Suite 406, 2465 East Bayshore Road, Palo Alto, CA, 94303, US

(21) Appl. No.: 10/679,927

(22) Filed: Oct. 6, 2003

(30) Foreign Application Priority Data
Nov. 29, 2002 (TW) 091134723

(51) Int. Cl. H01L 21/44

(52) U.S. Cl. 438/108; 438/107; 257/723; 257/724

(57) ABSTRACT

A compact electronic device includes at least a substrate, one semiconductor chip, one passive component, and a molding compound. A plurality of conductive traces are formed on a first surface of the substrate. A plurality of terminals are peripherally formed on a second surface of the substrate and externally exposed as the input/output connections of the compact electronic device. The conductive traces on the first surface are electrically connected to the terminals on the second surface by a plurality of vias. The semiconductor chip and the passive component are mounted on the first surface of the substrate and electrically connected to the substrate through a plurality of connectors. The molding compound covers the first surface of the substrate to encapsulate both the semiconductor chip and the passive components electrically connected to the substrate.

### CROSS-REFERENCE TO RELATED APPLICATION(S)

This application claims benefit under 35 USC 119 of corresponding Taiwan Application Serial No. 091134723 filed Nov. 29, 2002.

### FIELD OF THE INVENTION

The invention relates to compact electronic devices and manufacturing processes thereof, and more particularly, to an integrally packaged compact electronic device and a process of manufacturing the compact electronic device.

### BACKGROUND OF THE INVENTION

Information such as music, photos, images and news are widely downloaded digital media by means of, for example, a computer. Therefore, high-capacity compact storage media have been put into mass production. A portable flash device such as a multi-media card (MMC) became popular due to high capacity and high data transmission rate characteristics. The MMC is widely used in digital cameras, MP3 players, personal digital assistants (PDA), and other electronic products to quickly access and edit the stored information. It is a very convenient storage medium, especially when the electronic products are portable.

A multimedia card (MMC) package is an integrated circuit device, and usually includes a memory chip, a control chip, and passive components such as capacitors, resistors and inductors. The MMC package is used to store and process multimedia information such as digital photo and image data. The memory chip, the control chip and the passive components are mounted on a chip carrier such as a substrate and electrically connect thereto to enable functions of the electronic device.

FIG. 1A to FIG. 1D illustrate a conventional multimedia card package of the existing art. The multimedia card 1 includes a substrate 10 having a first surface 101 and a second surface 102. A plurality of conductive traces 11 are formed on the first surface 11 and a plurality of terminals 12 are formed on the second surface 102 as external connection points. The conductive traces 11 on the first surface 101 electrically connect to the terminals 12 on the second surface 102 through a plurality of vias (not shown) formed through the substrate. At least one semiconductor chip 13 is mounted on the first surface 101 of the substrate 10 and respectively connected to the substrate 10 through a plurality of wires 14. A molding compound 15 encapsulates the semiconductor chip 13 electrically connected to the substrate 10. At least one passive component 16 is mounted on and electrically connected to the first surface 101 of the substrate 10 at locations not covered by the molding compound 15. A plastic shell 17 encloses the first surface 101 and the second surface 102 of the substrate 10 to completely encapsulate the substrate 10 so as to protect the semiconductor chip 13 and the passive component 16 mounted thereon and electrically connected to the first surface of the substrate 10.

The multimedia card package is characterized in that the substrate 10 made of an organic material, such as a circuit board, has at least one semiconductor chip 13 mounted thereon. The chip 13 is electrically connected to the substrate 10 by a plurality of conductive wires 14 and then respectively electrically connected to corresponding terminals 12 through a plurality of vias (not shown). The terminals 12 are externally exposed as input/output connections of the multimedia card package and also provide external electrical connections to external devices (not shown). The epoxy resin covers the semiconductor chip 13, and an additional shell 17 is further provided to seal the substrate 10.

The above multimedia package has many disadvantages. For example, the double encapsulation achieved through the resin molding and the shell increases the production cost and the processing complexity. The passive components are mounted only on the surface of the substrate at locations not covered with the molding compound, which limits the trace routability and increases the complexity of the circuit design on the substrate. Furthermore, the multimedia card package is undesirably limited to the height of the double-encapsulated package and can not be further developed to be a multi-chip module (MCM) stack with multi-functionality, improved electrical properties, and high-speed operation.

Therefore, there is a need for a compact electronic device package that can be mass-produced with a reduced cost and a simplified process.

### SUMMARY OF THE INVENTION

It is therefore an objective of the invention to provide a compact electronic device and a process of manufacturing the compact electronic device, which can reduce production costs, simplify manufacturing procedures, and improve production yield.

It is another objective of the invention to provide a compact electronic device and a process of manufacturing the compact electronic device, which can provide multi-functionality, good electrical properties and high-speed operation for the compact electronic device.

In accordance with the above and other objectives, the compact electronic device of the invention includes a substrate, at least one semiconductor chip, at least one passive component and a molding compound. The substrate has a first surface and a second surface opposite to the first surface. A plurality of conductive traces are formed on the first surface. A plurality of terminals are peripherally formed on the second surface, and are externally exposed as input/output connections of the compact electronic device. The conductive traces on the first surface are electrically connected to the terminals on the second surface by a plurality of vias formed through the substrate. The semiconductor chip is mounted on the first surface of the substrate and electrically connected to the substrate through a plurality of electrical components. The passive component is mounted on and electrically connected to the first surface of the substrate. The molding compound covers the first surface of the substrate to encapsulate the semiconductor chip electrically connected to the substrate.

According to the invention, the process of integrally packaging a compact electronic device into a body further includes:

providing a substrate having a first surface and a second surface opposite to the first surface, wherein a chip and a passive component are mounted on and electrically connected to the first surface of the substrate, and a plurality of terminals formed at a periphery of the second service are externally exposed as input/output connections of the compact electronic device;

mounting at least one semiconductor chip and at least one passive component on the first surface of the substrate; and

applying a molding compound over the first surface of the substrate to encapsulate both the semiconductor chip and the passive component electrically connected to the substrate into a body.

The complete encapsulation of the substrate to seal the device, such as the semiconductor chip and the passive component, with the molding compound renders the manufacture process simpler and reduces the manufacturing cost. This contrasts with the prior art that requires both the molding compound and the addition of a shell to respectively cover the semiconductor chip and the substrate. The invention therefore allows for mass production and a reduction of the package thickness. Furthermore, the chip stack is easily achieved to provide the compact electronic device with multi-functionality, good electrical properties and high-speed operation. The entire substrate surface can be used for mounting with the semiconductor chip and the passive component, providing better trace routability with more room for layout design.

### BRIEF DESCRIPTION OF THE DRAWINGS

The present invention can be more fully understood by reading the following detailed description of the preferred embodiments, with reference made to the accompanying drawings wherein:

FIG. 1A (PRIOR ART) is a top view of a conventional multimedia card package;

FIG. 1B (PRIOR ART) is a bottom view of a conventional multimedia card package;

FIG. 1C (PRIOR ART) is a cross-sectional view of a conventional multi-media card package;

FIG. 1D (PRIOR ART) is a perspective view of a conventional multimedia card package;

FIG. 2A is a top view of a compact electronic device integrally packaged into a body according to a first embodiment of the invention;

FIG. 2B is a bottom view of a compact electronic device integrally packaged into a body according to a first embodiment of the invention;

FIG. 2C is a cross-sectional view of a compact electronic device integrally packaged into a body according to a first embodiment of the invention;

FIG. 3A is a top view of a compact electronic device integrally packaged into a body in batch according to a first embodiment of the invention;

FIG. 3B is a bottom view of a compact electronic device integrally packaged into a body in batch according to a first embodiment of the invention;

FIG. 4 is a cross-sectional view of a compact electronic device integrally packaged into a body according to a second embodiment of the invention; and

FIG. 5 is a cross-sectional view of a compact electronic device integrally packaged into a body according to a third embodiment of the invention.

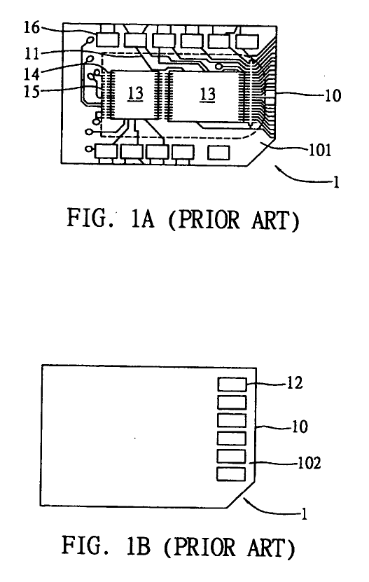

### DETAILED DESCRIPTION OF THE PREFERRED EMBODIMENTS

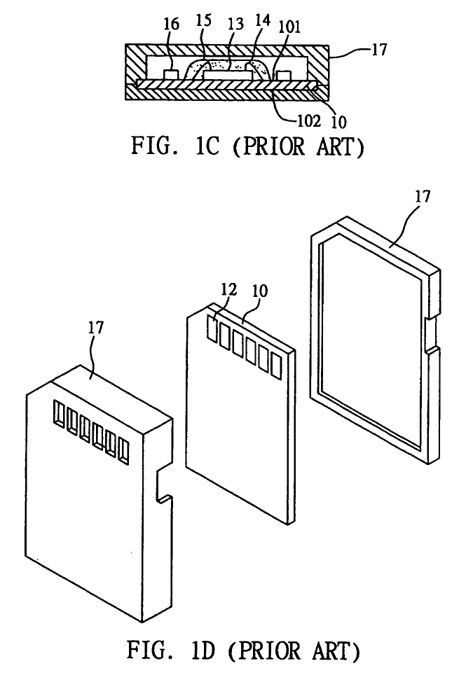

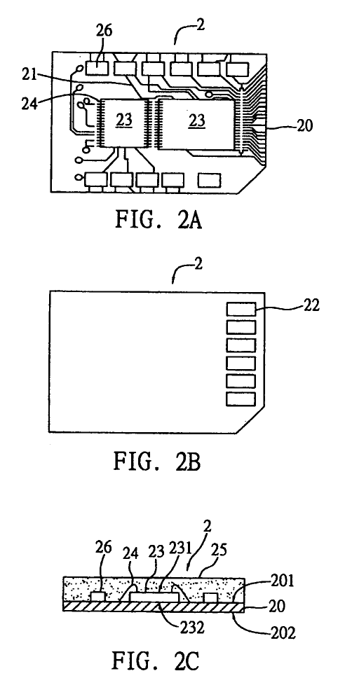

FIG. 2A to FIG. 2C illustrate a compact electronic device that is integrally packaged into a body according to one embodiment of the invention. FIG. 3A to FIG. 3B illustrate a process of integrally packaging a compact electronic device into a body according to one embodiment of the invention.

Referring to FIG. 2A to FIG. 2C, a compact electronic device 2 of the invention can be, for example, a multimedia card (MMC). The compact electronic device includes a substrate 20, at least one semiconductor chip 23, at least one passive component 26 and a molding compound 25. The substrate 20 has a first surface 201 and a second surface 202. The semiconductor chip 23 is attached on the first surface 201 of the substrate 20, and is electrically connected to the substrate 20 by a plurality of conductive elements 24. A conductive element 24 is, for example, a conductive wire such as a golden wire. The passive component 26 is attached and electrically connected to the first surface 201 of the substrate 20. The molding compound 25 covers the first surface 201 of the substrate 20 to encapsulate the electrical connection between the semiconductor chip 23 and the passive component 26.

The substrate 20 includes a first surface 201 and a second surface 202 opposite the first surface 201. A plurality of conductive traces 21 are formed on the first surface 201. A plurality of terminals 22 are formed at a periphery of the second surface 202 to externally expose the input/output terminals of the compact device 2. A plurality of vias (not shown) are formed through the substrate 20 to electrically connect the conductive traces 21 on the first surface 201 to the terminals 22 on the second surface 202. The semiconductor chip 23 and the passive component 26 are mounted and electrically connected to the first surface 201 of the substrate 20, so that external connection of the semiconductor chip 23 and the passive component 26 is achieved by the conductive traces 21, the vias, and the terminals 22. In order to protect the externally exposed terminals 22 from being oxidized in the ambient environment, a gold layer is usually formed over each terminal 22 as a protective layer, designated as a golden finger.

The semiconductor chip 23, such as a multimedia chip comprising an electrically erasable and programmable read only memory (EEPROM) chip and a control chip, has an active surface 231 and a non-active surface 232 opposite to the active surface 231. The non-active surface 232 of the chip 23 is attached on the first surface 201 of the substrate 20 by an adhesive. The active surface 231 of the chip 23 is electrically connected to the first surface 201 of the substrate 20 through a plurality of gold wires 24. Thereby, the compact electronic device 2 stores multimedia information such as digital photos and image data.

The passive component 26, such as a capacitor, resistor, or inductor, is electrically connected to the first surface 201 of the substrate 20 by the gold wires 24. Alternatively, the passive component 26 is electrically connected to the first surface 201 of the substrate 20 by surface mount technology (SMT) to increase or stabilize the electric performance of the compact electronic device.

The molding compound 25 can be, for example, an epoxy resin. After the semiconductor chip 23 and the passive component 26 are electrically connected to the substrate 20, the molding compound 25 encapsulates the first surface 201 of the substrate 20 so as to integrally package the compact electronic device 2 into a body.

The process of integrally packaging the electronic device into a body includes the following steps. A substrate 20 having a plurality of vias there through is provided. The semiconductor chip 23 and the passive component 26 are mounted on the substrate 20 by means of an adhesive such as an epoxy resin. The substrate is made, for example, of a material such as epoxy resin, polyimide resin, bismaleimide triazine (BT) resin or FR4 resin. The substrate has a first surface 201 and a second surface 202. A plurality of conductive traces 21 are formed on the first surface 201 to electrically connect the semiconductor chip 23 and the passive component 26 to the substrate 20 and, subsequently, to the externally exposed terminals 22 on the second surface 202 of the substrate 20.

Then, an encapsulation process is performed. The molding compound 25 such as epoxy resin is applied over the first surface 201 of the substrate 20 to cover the semiconductor chip 23 and the passive component 26 without needing a protective shell. Thereby, the compact electronic device 2 of the invention is constructed.

Referring to FIG. 3A and FIG. 3B, the multimedia card is packaged in batch by using a matrix substrate as a carrier. The matrix substrate 310 has a plurality of predefined packaging regions 311 for respectively mounting with a multimedia package structure 3. A trace layer is formed on each packaging region 311 to form a substrate 30 on which a semiconductor chip 33 and a passive component 36 are mounted. Then, the semiconductor chip 33 and the passive component 36 undergo a wire bonding process to electrically connect to the substrate 30. The substrate 30 is electrically connected to the semiconductor chip 33 and the passive component 36. Thereafter, the substrate 30 is placed in a mold and encapsulated with a molding compound 35. After the molding process, the substrate 30 with the multimedia package structures 3 is singulated by a sawing machine to obtain several multimedia package structures 3 at one time.

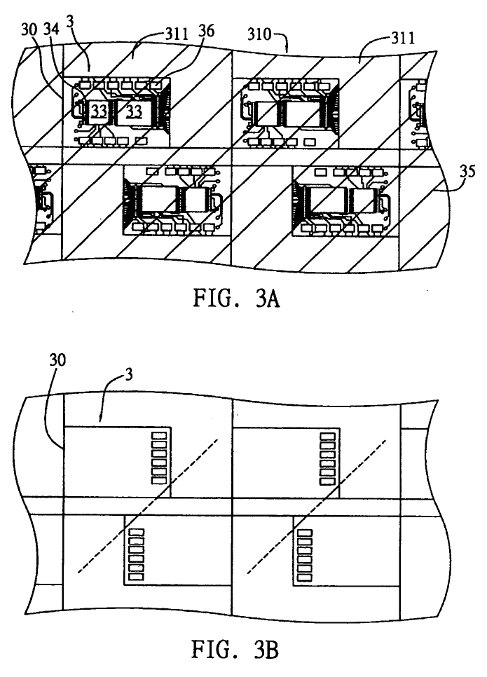

FIG. 4 is a cross-sectional view of an electronic device integrally packaged into a body according to a second embodiment of the invention. As shown, the process in the first embodiment is substantially the same as that of the second embodiment of the invention, except that a semiconductor chip 43 is electrically connected to a substrate 40 through a plurality of solder bumps 49 using flip chip technology.

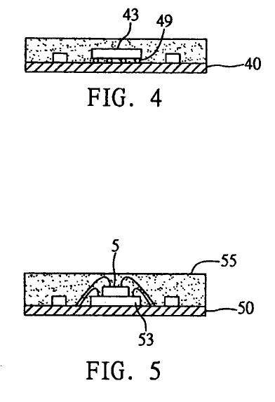

FIG. 5 is a cross-sectional view of an electronic device integrally packaged into a body according to a third embodiment of the invention. As shown, the process in the third embodiment is substantially the same as that of the second embodiment of the invention, except that a plurality of semiconductor chips 53 are stacked and respectively connected on a substrate 50. Therefore, the compact electronic device of the invention, having a multi chip module (MCM) stacked on its substrate, and further molded with a molding compound, provides advantages such as multi-functionality, improved electrical properties and high-speed operation.

In the invention, the complete encapsulation of the substrate to seal the device, such as the semiconductor chip and the passive component, with the molding compound renders the manufacturing process simpler and reduces the manufacturing cost. This contrasts with the prior art that requires both molding compound and additional shell to respectively cover the semiconductor chip and the substrate. The invention therefore allows for mass production and a reduction of the package thickness. Furthermore, the chip stack is easily achieved to provide the compact electronic device with multi-functionality, improved electrical properties and high-speed operation. The entire substrate surface can be used for mounting the semiconductor chip and the passive component, providing better trace routability with more room for layout design.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A process of manufacturing an integrally packaged compact electronic device, comprising the steps of:
providing a substrate having a first surface and a second surface opposite to the first surface, wherein at least one semiconductor chip and at least one passive component are mounted on and electrically connected to the first surface of the substrate, and a plurality of terminals are formed on the second surface and exposed outside to serve as input/output connections of the compact electronic device;
performing an encapsulation process to form an encapsulation body on the first surface of the substrate for integrally encapsulating the chip and the passive component.

2. The process of claim 1, wherein the compact electronic device is a multimedia card (MMC).

3. The process of claim 1, wherein a plurality of the semiconductor chips are stacked to form a multi chip module (MCM) and mounted on the substrate to provide the compact electronic device with multi-functionality, good electrical properties and high-speed operation.

4. The process of claim 1, wherein the semiconductor chip is selected from the group consisting of a multimedia chip, an electrically erasable and programmable read-only memory (EEPROM) chip, and a control chip.

5. The process of claim 1, wherein the passive component is selected from the group consisting of a capacitor, a resistor, and an inductor.

6. The process of claim 1, wherein the terminal is a golden finger.

7. A process of manufacturing an integrally packaged compact electronic device, comprising the steps of:
providing a matrix substrate having a plurality of pre-defined packaging regions each for forming the compact electronic device;
mounting at least one semiconductor chip and at least one passive component on each of the packaging regions;
electrically connecting the chips and the passive components to the substrate;
placing the substrate mounted with the chips and the passive components in a mold, and forming an encapsulation body to integrally encapsulate the chips and the passive components; and
singulating the substrate to cut through the encapsulation body and separate apart the plurality of packaging regions so as to form a plurality of the compact electronic devices.

8. The process of claim 7, wherein the compact electronic device is a multimedia card (MMC).

9. The process of claim 7, wherein a plurality of the semiconductor chips are stacked to form a multi chip module (MCM) and mounted on each packaging region of the substrate to provide the compact electronic device with multi-functionality, good electrical properties and high-speed operation.

10. The process of claim 7, wherein the semiconductor chip is selected from the group consisting of a multimedia chip, an electrically erasable and programmable read-only memory (EEPROM) chip, and a control chip.

11. The process of claim 7, wherein the passive component is selected from the group consisting of a capacitor, a resistor, and an inductor.

12. A compact electronic device, comprising:
a substrate having a first surface and a second surface opposite to the first surface, wherein a plurality of conductive traces are formed on the first surface, and a plurality of terminals are formed on the second surface and exposed outside to serve as input/output connections of the compact electronic device, and wherein the conductive traces on the first surface are electrically connected to the terminals on the second surface by a plurality of vias formed through the substrate;
at least one semiconductor chip mounted on the first surface of the substrate and electrically connected to the substrate through a plurality of conductive elements;
at least one passive component mounted on and electrically connected to the first surface of the substrate; and
an encapsulation body formed on the first surface of the substrate for integrally encapsulating the chip and the passive component.

13. The compact electronic device of claim 12, wherein the compact electronic device is a multimedia card (MMC).

14. The compact electronic device of claim 12, wherein a plurality of the semiconductor chips are stacked to form a multi chip module (MCM) and mounted on the substrate to provide the compact electronic device with multi-functionality, good electrical properties and high-speed operation.

15. The compact electronic device of claim 12, wherein the semiconductor chip is selected from the group consisting of a multimedia chip, an electrically erasable and programmable read-only memory (EEPROM) chip, and a control chip.

16. The compact electronic device of claim 12, wherein the passive component is selected from the group consisting of a capacitor, a resistor, and an inductor.

17. The compact electronic device of claim 12, wherein the conductive element is a conductive wire.

18. The compact electric device of claim 12, wherein the terminal is a golden finger.
